(19) United States
(12) Patent Application Publication
(10) Pub. No.: US 2009/0295490 A1
(43) Pub. Date: Dec. 3, 2009

(54) DDS CIRCUIT AND ELECTRONIC DEVICE HAVING THE SAME

(75) Inventors: Koji NAKAMUTA, Kawasaki (JP); Yoshito KOYAMA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/366,220

(22) Filed: Feb. 5, 2009

(30) Foreign Application Priority Data
May 30, 2008 (JP) 2008-142085

(51) Int. Cl. H03L 7/00

(52) U.S. Cl. 331/18

(57) ABSTRACT

A circuit includes a DDS unit deriving a sine wave from a tuning word using a frequency of a reference clock, a first frequency divider dividing the frequency of the reference clock, a second frequency divider dividing a frequency of the sine wave output by the DDS unit, and a mixer mixing the sine wave of a divided frequency with the reference clock of a divided frequency to thus produce the sine wave of a mixed frequency.

### CROSS-REFERENCE TO RELATED APPLICATION

This application is based upon and claims the benefit of priority of the prior Japanese Patent Application No. 2008-142085, filed on May 30, 2008, the entire contents of which are incorporated herein by reference.

### FIELD

The embodiments described herein relate to DDS (Direct Digital Synthesizer) circuits.

### BACKGROUND

The DDS circuit is widely used as a signal generator in the fields of, for example, car radios, data communication systems, image processing apparatuses for medical use and radar transmitter/receiver equipment. For example, the radar transmitter/receiver equipment uses the DDS circuit together with a PLL (Phase Locked Loop) circuit, as described in Japanese Patent Application Publication No. 11-150421. By way of another example, the DDS circuit has a built-in frequency divider, as disclosed in Japanese patent Application Publication No. 11-289224.

The frequency of the output signal of the DDS circuit is described by expression (1):

$${F}_{dds} = {F}_{refclk} \cdot \frac{T W}{{2}^{NA}} \qquad ( 1 )$$

where F_{dds} is the frequency of the output signal, F_{refclk} is the frequency of a reference clock, TW is a tuning word, and NA is the bit length of the tuning word. In practice, the frequency F_{dds} of the output signal is limited to a frequency equal to TW/2^{NA} times the frequency F_{refclk} of the reference clock due to the influence of noise. For example, the limited frequency of the output signal is approximately ⅓ of the frequency F_{refclk} of the reference clock.

The resolution R_{SLN} of the frequency of the output signal is described by expression (2):

$${R}_{SLN} = \frac{{F}_{refclk}}{{2}^{NA} \times {F}_{dds}} \qquad ( 2 )$$

Expression (2) indicates that the resolution R_{SLN} is the inverse of the tuning word TW. The resolution R_{SLN} becomes better as the calculation result of expression (2) becomes smaller.

As described above, F_{refclk}/F_{dds} is approximately equal to 3. Thus, improvements in resolution may be achieved by increasing the bit length NA of the tuning word TW. However, this may increase the circuit scales of an accumulator and a memory that form the DDS circuit and is therefore not desirable in terms of production cost and mounting.

### SUMMARY

According to an aspect of the present invention, there is provided a circuit including: a DDS unit deriving a sine wave from a tuning word using a frequency of a reference clock; a first frequency divider dividing the frequency of the reference clock; a second frequency divider dividing a frequency of the sine wave output by the DDS unit; and a mixer mixing the sine wave of a divided frequency with the reference clock of a divided frequency to thus produce the sine wave of a mixed frequency.

### BRIEF DESCRIPTION OF DRAWINGS

FIG. 1 is a block diagram of a DDS circuit according to a first embodiment of the present invention;

FIG. 2 is a block diagram of a DDS unit of the DDS circuit illustrated in FIG. 1;

FIG. 3 is a waveform diagram of signal waveforms observed in the DDS circuit illustrated in FIG. 1;

FIG. 4 is a block diagram of an exemplary configuration of an additional circuit used in the DDS circuit illustrated in FIG. 1;

FIG. 5 is a block diagram of an LSI chip that is an electronic device according to an aspect of the present invention; and

FIG. 6 is a block diagram of a printed-circuit board that is another electronic device according to another aspect of the present invention.

### DESCRIPTION OF EMBODIMENTS

A description will now be given, with reference to the accompanying drawings, of embodiments of the present invention.

### First Embodiment

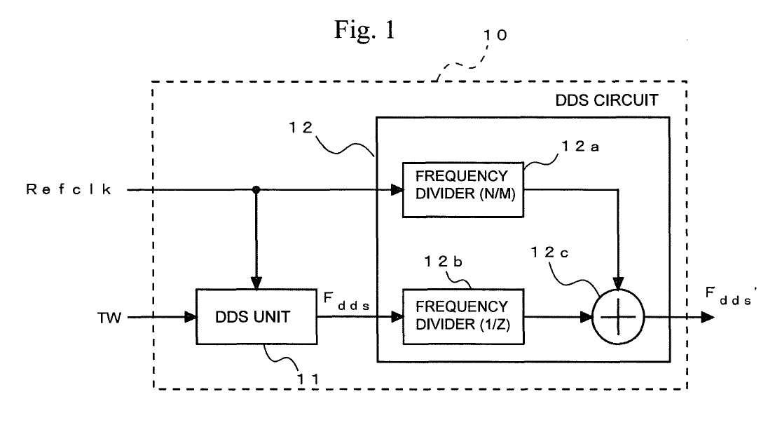

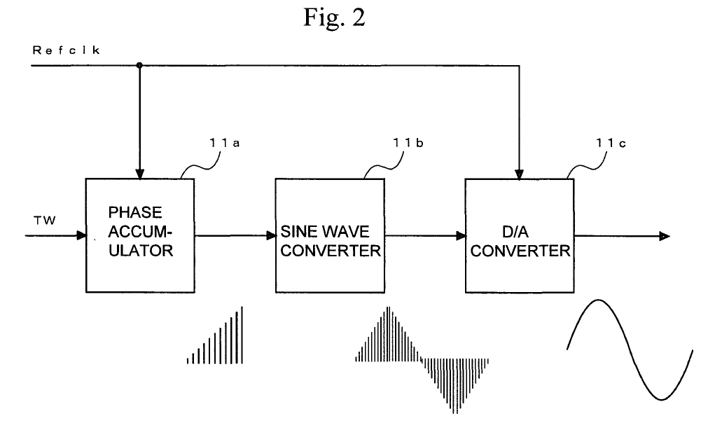

FIG. 1 is a block diagram of a DDS circuit 10 according to a first embodiment of the present invention, and FIG. 2 is a block diagram of a DDS unit 11 in the DDS circuit 10 depicted in FIG. 1. The DDS circuit includes an additional circuit 12 connected to the DDS unit 11.

The DDS unit 11 is configured as illustrated in FIG. 2. More particularly, the DDS unit 11 is composed of a phase accumulator 11a, a sine wave converter 11b, and a D/A converter 11c. Waveforms illustrated between the blocks indicate changes of a tuning word TW applied to the phase accumulator 11a. The phase accumulator 11a may be composed of a full adder and a latch. The phase accumulator 11a receives the tuning word TW, which is a digital control code, and accumulates it by using a frequency F_{refclk} of a reference clock R_{efclk}, more specifically, in synchronism with the frequency F_{refclk}. The accumulated tuning word TW is output to the sine wave converter 11b.

The sine wave converter 11b may be composed of a memory such as a ROM (Read Only Memory) or a RAM (Random Access Memory). The memory stores a lookup table for converting the accumulated tuning word TW into a sine wave, which is a digital signal. Then, the sine wave derived from the received tuning word TW is applied to the D/A converter 11c. The D/A converter 11c converts the tuning word TW of the digital signal into an analog signal of the tuning word TW in synchronism with the reference clock R_{efclk}.

The additional circuit 12 is described with reference to FIG. 1. The additional circuit 12 is composed of a frequency divider 12a, another frequency divider 12b and a mixer 12c. The additional circuit 12 may be implemented by an FPGA (Field Programmable Gate Array), discrete components, or an ASIC (Application Specific Integrated Circuit). The additional circuit 12 may be incorporated into the DDS circuit 10. The DDS circuit 10 may be separate from the DDS circuit 10 and may be externally connected to the DDS circuit 10.

The frequency dividers 12a and 12b may be formed by programmable counters, which enable the resolution to be arbitrarily changed. The frequency divider 12a divides the frequency of the reference clock R_{efclk} at a frequency dividing ratio of N/M where N and M are respectively frequency dividing ratio setting values of a frequency dividing condition for the frequency divider 12a, and M is greater than or equal to N (N≦M). The divided frequency derived from the reference clock R_{efclk} is applied to the mixer 12c. The frequency divider 12b divides the frequency of the reference clock R_{efclk} at a frequency dividing ratio of 1/Z where Z is a frequency dividing ratio setting value of a frequency dividing condition for the frequency divider 12b. The divided frequency derived from the reference clock R_{efclk} is applied to the mixer 12c.

The mixer 12c produces a sine wave of a mixed frequency obtained by mixing the divided frequency of the reference clock output by the frequency divider 12a and the divided frequency of the sine wave output by the frequency divider 12b.

A description will now be given of improvements in the resolution of a frequency F_{dds}′ of the sine wave output by the DDS circuit 10. The output frequency F_{dds}′ of the DDS circuit 10 is described by expression (3):

$${F}_{dds}^{′} = \frac{{F}_{dds}}{Z} + {F}_{refclk} \cdot \frac{N}{M} \qquad ( 3 )$$

By inserting expression (1) into expression (3), the output frequency F_{dds}′ is rewritten as expression (4):

$$\begin{matrix}{F}_{dds}^{′} = \frac{{F}_{refclk} \times \frac{T W}{{2}^{NA}}}{Z} \times {F}_{refclk} \cdot \frac{N}{M} \\ = \frac{{F}_{refclk} \times T W}{Z \times {2}^{NA}} + {F}_{refclk} \cdot \frac{N}{M} \\ = {F}_{refclk} ( \frac{T W}{Z \times {2}^{NA}} + \frac{N}{M} )\end{matrix} \qquad ( 4 )$$

As described above, the frequency F_{dds}′ of the output signal of the DDS circuit 10 is equal to a given multiple of the frequency F_{refclk} of the reference clock R_{efclk}. Thus, by changing the frequency dividing ratio setting values M, N and Z of the frequency dividers 12a and 12b, the frequency F_{dds}′ of the signal output from the additional circuit 12 can be improved so as to be equal to or higher than the frequency F_{refclk} of the reference clock. For example, when M=6, N=5 and Z=2, the frequencies F_{dds}′ and F_{refclk} are equal to each other. In contrast, the frequency F_{dds} of the output signal of the DDS unit 11 in the conventional configuration without the additional circuit 12 is approximately equal to only ⅓ of the frequency F_{refclk} of the reference clock.

The resolution R_{SLN} is the quantity of variation in frequency per a tuning word TW of 1, and is described as expression (5):

$$\begin{matrix}{R}_{SLN} = \frac{{F}_{refclk} ( \frac{T W}{Z \times {2}^{NA}} + \frac{N}{M} ) - {F}_{refclk} ( \frac{T W - 1}{Z \times {2}^{NA}} + \frac{N}{M} )}{{F}_{dds}^{′}} \\ = \frac{{F}_{refclk} ( \frac{T W}{Z \times {2}^{NA}} - \frac{T W - 1}{Z \times {2}^{NA}} )}{{F}_{dds}^{′}} \\ = \frac{{F}_{refclk} ( \frac{1}{Z \times {2}^{NA}} )}{{F}_{dds}^{′}} \\ = \frac{1}{Z} \times \frac{{F}_{refclk}}{{2}^{NA} \times {F}_{dds}^{′}}\end{matrix} \qquad ( 5 )$$

It can be seen from comparison between expressions (2) and (5), according to the present embodiment, the resolution is improved so as to be reduced to 1/Z times the conventional resolution when the frequency F_{dds} of the sine wave output from the DDS unit 11 and the signal F_{dds}′ of the sine wave output from the mixer 12c become approximately equal to each other, preferably, just equal to each other.

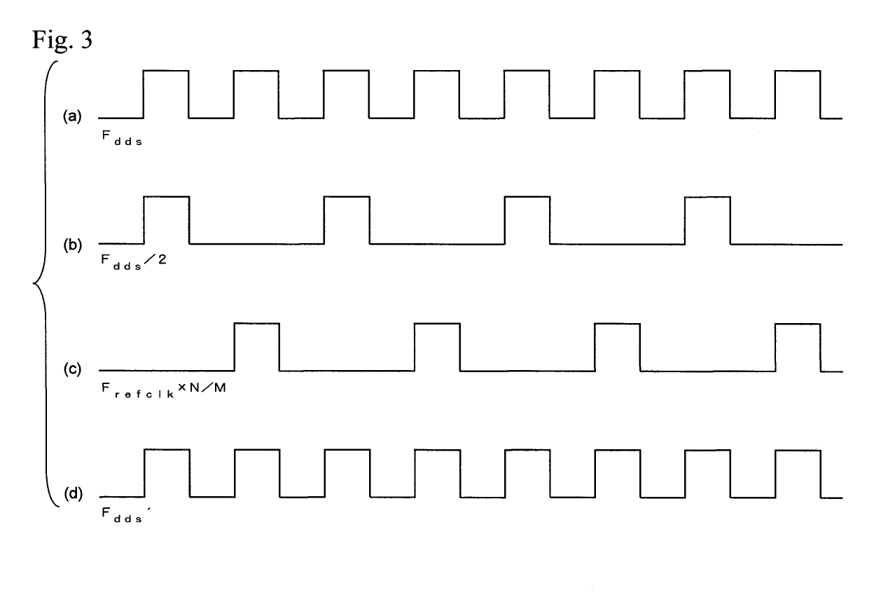

FIG. 3 is a waveform diagram of the signals observed in the DDS circuit 10. Part (b) of FIG. 3 illustrates a waveform observed when the frequency dividing ratio setting value Z of the frequency divider 12b is set equal to 2. In this case, the frequency F_{dds} of the output signal of the DDS unit 11 depicted in part (a) of FIG. 3 is divided by the frequency divider 12b, so that the waveform depicted in part (b) of FIG. 3 can be obtained.

The frequency F_{refclk} of the reference clock R_{efclk} is divided by the frequency divider 12a, and the resultant frequency is as depicted in part (c) of FIG. 3. The frequency F_{refclk} is combined with the frequency F_{dds} by the mixer 12c, and the frequency F_{dds}′ of the output signal of the DDS circuit 10 is as depicted in part (d) of FIG. 3.

As described above, the resolution of the frequency F_{dds}′ can be improved when the frequency F_{dds} of the sine wave output by the DDS unit 11 is approximately equal to the frequency F_{dds}′ of the sine wave output by the mixer 12c. The frequencies F_{dds} and F_{dds}′ are approximately equal to each other when M and N are respectively equal to, for example, 6 and 1 for Z of 2. Arbitrary values of M, N and Z may be selected as long as F_{dds} and F_{dds}′ are approximately equal to each other.

### Second Embodiment

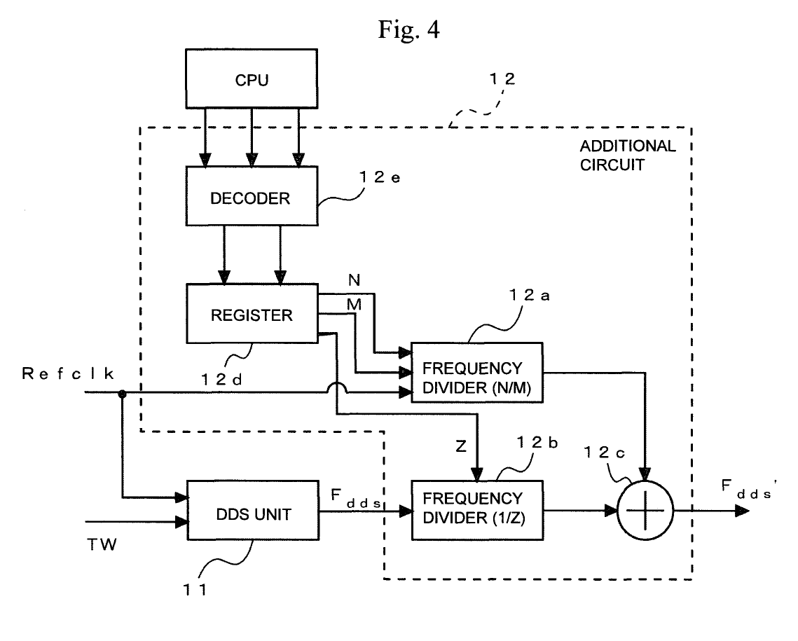

A second embodiment is described by referring to FIG. 4, which illustrates another configuration of the additional circuit 12. Parts that are the same as those illustrated in FIG. 1 are given the same reference numerals, and a description thereof is omitted here. The configuration of the additional circuit 12 illustrated in FIG. 4 differs from that in FIG. 1 in that the additional circuit 12 in FIG. 4 includes a register 12d and a decoder 12e. The register 12d is used to store the frequency dividing conditions on the frequency dividers 12a and 12b, more specifically, the frequency dividing ratios of the frequency dividers 12a and 12b. More particularly, the register 12d stores the frequency dividing ratio setting values M and N for the frequency divider 12a and the frequency dividing ratio setting value Z for the frequency divider 12b. These values are output by the decoder 12e and are set in the register 12d. In practice, a control signal for writing is applied to the register 12d from the decoder 12e along with the values to be written. A CPU (Central Processing Unit), which may be externally connected to the additional circuit 12, sends data to be decoded to the decoder 12e. The CPU is a controller that controls the decoder 12e.

According to the second embodiment, the frequency dividing ratios of the frequency dividers 12a and 12b can be changed under the control of the controller externally provided to the additional circuit 12. It is thus possible to alter the resolution of the frequency F_{dds}′ of the sine wave output by the DDS circuit 10.

### Third Embodiment

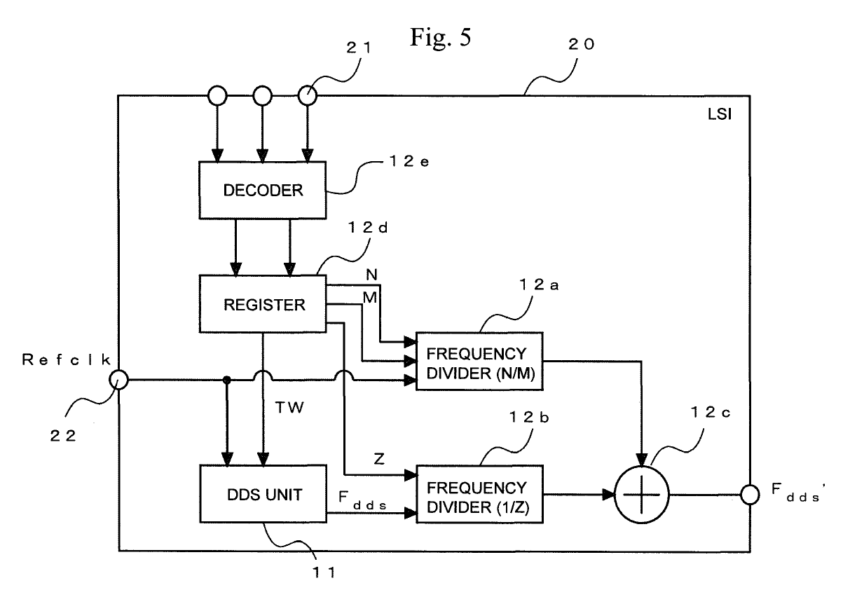

FIG. 5 is a block diagram of an exemplary configuration of an LSI (Large-Scale Integration) chip 20, which is an example of the electronic device according to an aspect of the present invention. In FIG. 5, parts that are the same as those previously illustrated in FIGS. 1 and 4 are given the same reference numerals. The electronic device according to an aspect of the present invention includes a communications apparatus such as a radar transmitter/receiver equipment, a measurement instrument, and an image processing apparatus for medical use.

The LSI chip 20 is configured so that the DDS unit 11 and the additional circuit 12 employed in the second embodiment are integrated. The LSI chip 20 may have another configuration in which the DDS circuit 10 used in the first embodiment, the register 12d and the decoder 12e are integrated. The LSI chip 20 has multiple terminals 21 connected to the decoder 12e, and a terminal 22 connected to the DDS unit 11 and the frequency divider 12a. The above-mentioned CPU may be connected to the decoder 12e through the terminals 21. An oscillator for generating the reference clock R_{efclk} may be connected to the terminal 22. The LSI chip 20 has an output terminal through which the output signal of the frequency F_{dds}′ is output.

### Fourth Embodiment

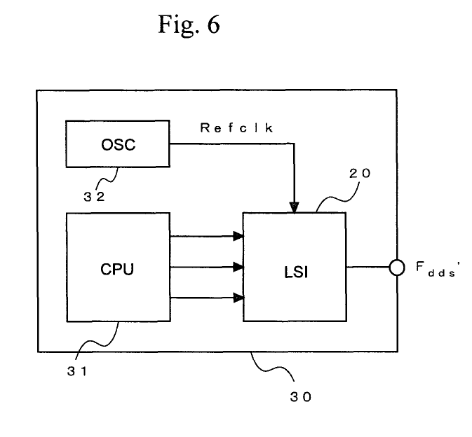

FIG. 6 is a block diagram of an exemplary configuration of a printed-circuit board, which is another example of the electronic device according to an aspect of the present invention. The printed-circuit board 30 has a board on which the LSI chip 20 used in the third embodiment, a CPU 31 and an oscillator 32 are formed. The CPU 31 sends data, control and address signals to the LSI chip 20 in order to control the LSI chip 20.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A circuit comprising:
a DDS unit deriving a sine wave from a tuning word using a frequency of a reference clock;
a first frequency divider dividing the frequency of the reference clock;
a second frequency divider dividing a frequency of the sine wave output by the DDS unit; and
a mixer mixing the sine wave of a divided frequency with the reference clock of a divided frequency to thus produce the sine wave of a mixed frequency.

2. The circuit according to claim 1, wherein at least one of the first and second frequency dividers includes a programmable counter.

3. The circuit according to claim 1, wherein the first frequency divider divides the frequency of the reference clock so that the mixed frequency is approximately equal to the frequency of the sine wave output by the DDS unit.

4. The circuit according to claim 2, wherein the first frequency divider divides the frequency of the reference clock so that the mixed frequency is approximately equal to the frequency of the sine wave output by the DDS unit.

5. An electronic device comprising:
a DDS unit deriving a sine wave from a tuning word using a frequency of a reference clock;
a memory storing frequency dividing conditions on the frequency of the reference clock and a frequency of the sine wave;
a first frequency divider dividing the frequency of the reference clock on the frequency dividing condition on the frequency of the reference clock stored in the memory;
a second frequency divider dividing the frequency of the sine wave output by the DDS unit on the frequency of the sine wave stored in the memory; and
a mixer mixing the sine wave of a divided frequency with the reference clock of a divided frequency to thus produce the sine wave of a mixed frequency.

6. An electronic device comprising:
an oscillator generating a reference clock;
a DDS unit deriving a sine wave from a tuning word using a frequency of the reference clock;
a memory storing frequency dividing conditions on the frequency of the reference clock and a frequency of the sine wave;
a first frequency divider dividing the frequency of the reference clock on the frequency dividing condition on the frequency of the reference clock stored in the memory;
a second frequency divider dividing the frequency of the sine wave output by the DDS unit on the frequency of the sine wave stored in the memory; and
a mixer mixing the sine wave of a divided frequency with the reference clock of a divided frequency to thus produce the sine wave of a mixed frequency.
